(19) United States
(12) Patent Application Publication
(10) Pub. No.: US 2013/0320466 A1
(43) Pub. Date: Dec. 5, 2013

(54) Package for Damping Inertial Sensor

(71) Applicants: Li Chen, Belmont, MA (US); Kuang L. Yang, Newton, MA (US)

(72) Inventors: Li Chen, Belmont, MA (US); Kuang L. Yang, Newton, MA (US)

(73) Assignee: ANALOG DEVICES, INC., Norwood, MA (US)

(21) Appl. No.: 13/484,567

(22) Filed: May 31, 2012

(51) Int. Cl. H01L 29/84; H01L 21/02

(52) U.S. Cl. 257/417; 438/50; 257/E29.324; 257/E21.002

(57) ABSTRACT

A capped micromachined accelerometer with a Q-factor of less than 2.0 is fabricated without encapsulating a high-viscosity gas with the movable mass of the micromachined accelerometer by providing small gaps between the movable mass and the substrate, and between the movable mass and the cap. The cap may be an silicon cap, and may be an ASIC smart cap.

### TECHNICAL FIELD

The present invention relates to inertial sensors, and more particularly to packaging for inertial sensors.

### BACKGROUND ART

It is known in the prior art to enclose micromachined (“MEMS”) inertial sensor in a package, to protect the inertial sensor from damage. Some inertial sensors are hermetically sealed to maintain a desired atmosphere and environment. A typical MEMS inertial sensor includes at least one movable component movably suspended above a substrate. The substrate and movable component face each other across a gap, and have dimensions that are large relative to the gap.

In the case of an accelerometer, the movable component may be known as a “beam.” The inertia of the beam will cause the beam to be displaced relative to the substrate when the accelerometer is subjected to an acceleration. The quantity of such displacement is a function of the acceleration, as well as the properties of the beam and its suspension system. The sensitivity of the accelerometer is a function of the displacement of the beam; the greater the displacement under a given acceleration, the greater the sensitivity of the accelerometer. Generally, therefore, the suspension of the beam is configured to allow maximum displacement of the beam while ensuring acceptable linearity.

In normal operation, the substrate and movable component do not come into contact. However, if the moveable component approaches the substrate or other surface, the opposing (or “facing”) surfaces may adhere to one another, in a phenomenon commonly known as “stiction.”

Stiction is a dominant failure mechanism in micromachined devices, and can arise in a variety of ways. Stiction may arise, for example, when interfacial forces between two opposing faces of a micromachined device exceed the restoring forces of the suspension system. The stiction forces may include capillary forces, chemical bonding, electrostatic forces, and van der Waals forces.

To reduce the risk of stiction, packing for MEMS devices typically leaves a generous gap between the movable component and the surface of the packaging.

### SUMMARY OF THE EMBODIMENTS

In a first embodiment there is provided an accelerometer having a Q-factor of less than 2.0, the accelerometer including a substrate having a substrate surface; a movable mass suspended from the substrate, the movable mass having a first surface and a second surface opposite the first surface, the first surface facing the substrate surface and separated from the substrate surface by a first gap; a cap having a cap surface, the cap coupled to the substrate and forming a hermetically sealed volume with the substrate and enclosing the movable mass, wherein the second surface is opposite the cap surface and is separated from the cap surface by a second gap; and a gas filling the volume at a pressure of less than 1 atmosphere, the gas having a viscosity of less than 25.0 μPa·s, in which each of the first gap and the second gap being less than 10 um, such that the accelerometer has a Q-factor of less than 2.0.

In some embodiments, the gas is at a pressure below 0.5 atmospheres.

Some embodiments include at least one standoff on the cap surface, and in some embodiments the standoff is opposite the second surface when the movable mass is in a rest position.

Some embodiments include a frit between the substrate and the cap, the frit securing the substrate to the cap and forming a hermetic seal between the substrate and the cap.

Some embodiments also include a mesa, and a surface of the mesa is a part or portion of the cap surface, while in some embodiments the mesa includes two or more mesa portions.

Some embodiments include a number of standoffs around, or even on a surface of, a mesa.

In some embodiments, the substrate includes a mesa, and a surface of the mesa is a part or portion of the substrate surface. Some embodiments include one or more standoffs around the mesa portion of the substrate.

In another embodiment there is provided a method of fabricating an accelerometer having a Q-factor of less than 2.0, the method including the steps of providing a substrate having a substrate surface; suspending a movable mass from the substrate, the movable mass having a first surface and a second surface opposite the first surface, the first surface facing the substrate surface and separated from the substrate surface by a first gap; providing a gas around the substrate at a pressure of less than 1 atmosphere, the gas having a viscosity of less than 25.0 μPa·s; providing a cap, the cap having a cap surface; and mounting the cap to the substrate such that the second surface is opposite the cap surface and is separated from the cap surface by a second gap, and such that the substrate and cap form a hermetically sealed volume and enclose the movable mass and trap some of the gas within the volume, such that each of the first gap and the second gap is less than 10 um, and such that the accelerometer has a Q-factor of less than 2.0.

In some embodiments, the step of providing a gas around the substrate includes providing a gas around the substrate at a pressure of less than 0.5 atmospheres, the gas having a viscosity of less than 25.0 μPa·s.

In some embodiments, the cap includes at least one standoff on the cap surface, and in some embodiments the standoff is opposite the second surface when the movable mass is in a rest position.

In some embodiments, the method also includes providing a frit between the substrate and the cap, the frit securing the substrate to the cap and forming a hermetic seal between the substrate and the cap.

In some embodiments, the step of providing a cap further includes providing a cap having a mesa, and a surface of the mesa being a part or portion of the cap surface. In some embodiments, the mesa includes a plurality of mesa portions.

In some embodiments, the step of providing a cap further includes, providing a cap includes providing a cap that has two or more standoffs around the mesa.

In some embodiments, the step of providing a substrate includes providing a substrate having a mesa, and a surface of the mesa is a part or portion of the substrate surface. In some embodiments, the step of providing a substrate having a mesa further includes providing a substrate having two or more standoffs around the mesa.

### BRIEF DESCRIPTION OF THE DRAWINGS

The foregoing features of embodiments will be more readily understood by reference to the following detailed description, taken with reference to the accompanying drawings, in which:

FIGS. 1A and 1B schematically illustrate a low-Q accelerometer according to a first embodiment;

FIG. 2 schematically illustrates a prior art accelerometer;

FIGS. 3A-3B schematically illustrate Q-factor;

FIG. 4 is a graph that schematically illustrates the Q-factor of various accelerometers as a function of a variety of fill gasses and the pressure of the variety of fill gasses;

FIGS. 5A-5D schematically illustrate alternate embodiments;

FIGS. 6A-6D schematically illustrate alternate embodiments;

FIG. 7 schematically illustrates an embodiment of a method of fabricating an accelerometer.

### DETAILED DESCRIPTION OF SPECIFIC EMBODIMENTS

Various embodiments provide an accelerometer in which the proof mass is encapsulated in a low-viscosity gas, and yet the accelerometer has a dampened response to shock acceleration, or dynamic acceleration, have a frequency component at or near the accelerometer's resonant frequency (fo). Embodiments are easy to manufacture, and provide the additional benefit that they can be fabricated without encapsulating a high-viscosity gas within the accelerometer. In addition, various embodiments provide an easy way to detect when a packaged accelerometer has lost its hermetic seal.

Typically, accelerometers are designed and manufactured to have a pronounced response to an applied acceleration at a frequency well below the accelerometer's resonant frequency, because such a response tends to desirably increase the sensitivity of the accelerometer, for example if the accelerometer is of the capacitive type. Generally, the greater the displacement of the beam, the greater the change in capacitance. For that reason, the suspension system in an accelerometer is typically configured to be sufficiently rigid so as to suspend the beam above a supporting substrate, but to be sufficiently compliant so as to avoid hindering the displacement of the beam. As such, the response of the accelerometer depends, in part, on the compliance of the accelerometer's internal suspension system.

In some applications, such as those in which higher frequency, lower acceleration amplitude shock events occur regularly, an undesirable over-drive acceleration response may occur when the shock frequency is at or near the accelerometer's resonant frequency (fo). The term “shock frequency” refers to the frequency spectrum of a wave caused from one shock (i.e., a physical impulse). Such a wave may be a dynamic vibration wave, with frequency or frequency components that vary (e.g., in a non-linear system) depending on the properties of the accelerometer and the way the wave interacts with the accelerometer and its media/environment. A shock event, in turn, may be a single shock, or multiple shocks. Even a single shock may have a frequency spectrum that includes the accelerometer's resonant frequency, or a harmonic of that resonant frequency, while multiple shocks may even occur at a frequency that includes the accelerometer's resonant frequency, or at a harmonic of that resonant frequency. In such scenarios, the sensor may fail to function properly or produce false alarm as the sensor moving structure could be stuck or damage, or to some lesser degree, send wrong output signal as if the much higher acceleration load apply. As such, in some applications, a dampened response is desirable. For example, sensors with a damping performance requirement for over-load protection are used in applications such as automotive and industrial fields where common shock events happen regularly, and have a frequency component at a frequency around the sensor's resonating frequency (fo).

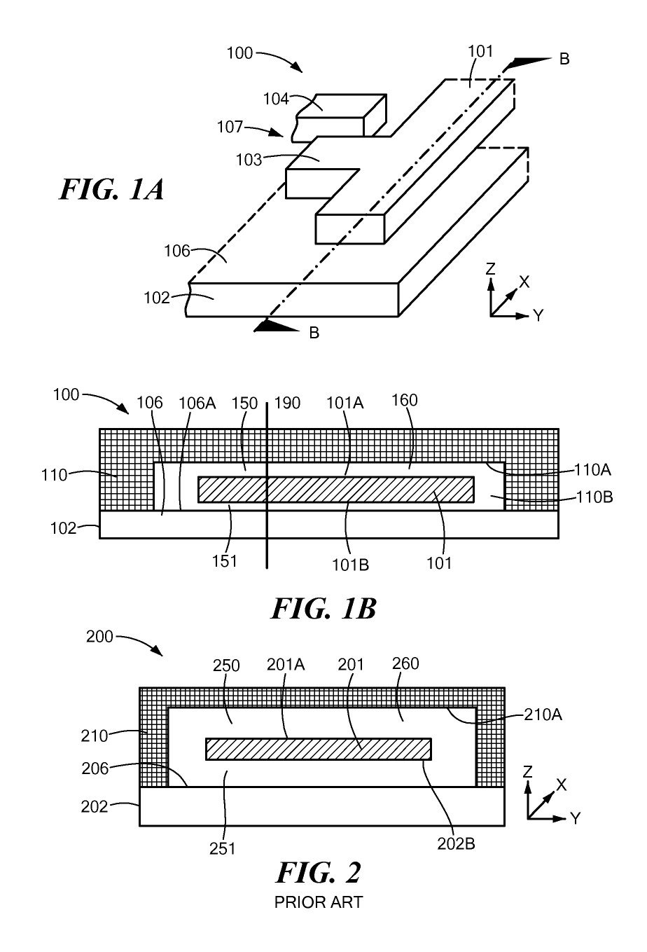

To that end, an illustrative embodiment of a micromachined accelerometer 100 according to the present application is schematically illustrated in FIG. 1A. In accelerometer 100, a mass (or “beam”) 101 is suspended by a compliant suspension system (not shown) above a substrate 102. FIG. 1B schematically illustrates a cross-section of accelerometer 100 along line B-B, covered by a cap 110. In accelerometer 100, beam 101 is sandwiched between the inner surface 110A of cap 110 and the inner surface 106A of substrate 102. In particular, a straight line 190 through the beam 101, and normal to the surface 101A of the beam 101, would pass through the cap 110 and the substrate 102, and indeed would be normal to the surfaces 110A and 106A, respectively. These physical relationships may also apply to various embodiments described below.

When the accelerometer 100 is not subject to an acceleration, the beam 101 remains suspended above the substrate 102 in a position that may be known as its “nominal” or “rest” position, and does not move relative to the substrate 102. However, when the substrate 102 is subjected to an acceleration, for example in the +X direction, the inertia of the beam 101 causes a displacement of the beam 101 in the -X relative to the substrate 102. A finger 103 on the beam 101 forms a variable capacitor across gap 107 with a counterpart finger 104 on the substrate 102. The capacitance varies when the beam 101 moves relative to the substrate 102. The variable capacitance can be electronically processed to produce an electrical signal representing the displacement of the beam, and the signal therefore represents the acceleration.

In the accelerometer 100 of the embodiment of FIGS. 1A and 1B, the gap 150 between the top surface 101A of beam 101 and the inner surface 110A of cap 110 is controlled to be within a specific range of distances. For example, in one embodiment, the gap 150 is not greater than 10 micrometers (10 um, where the term micrometers is abbreviated as “um”), and in some embodiments is less than 5 micrometers. For example, some embodiments have gaps of 2 um, 3 um or 4 um. In addition, the volume within the cap (i.e., the volume formed by the cap 110 and the substrate 102, in which the beam is encapsulated) is hermetically sealed, and filled with a low-viscosity gas. For example, the low-viscosity gas may have a viscosity of less than 25.0 μPa·s (25 micro Pascal-second). Examples of such low-viscosity gas include N2 (with a viscosity of approximately 21 μPa·s at room temperature) and forming gas (a mixture of hydrogen and nitrogen), to name but a few. Such gases have the benefit of being commonly found in semiconductor fabrication facilities. Note that, as used in this description and the accompanying claims, the viscosity of all gases is specified at room temperature, which is approximately 25 degrees centigrade.

The inventors have discovered that the behavior of a low-viscosity gas (including many common gases) in such a narrow gap is such that the gas acts to dampen motion of the beam, thereby producing a response to the near-fo shock frequencies (i.e., frequencies near the resonant frequency of the beam) that is less pronounced acceleration than in prior art accelerometers with larger gaps if filled with the same gas.

The accelerometer 100 of FIGS. 1A and 1B illustrates a number of contrasts with prior art accelerometers. For example, a prior art accelerometer 200 is schematically illustrated in FIG. 2, and includes a beam 201 suspended above substrate 202 and within a volume 260 formed by substrate 202 and cap 210. The accelerometer 200 has a compliant suspension. Such a suspension, however, may present a number of concerns.

One such concern is the risk of stiction. For example, ideally, the beam 201 remains suspended above the substrate 202 at all times; in other words, the motion of the beam 201 relative to the substrate 202 occurs within a plane above, and parallel to, the substrate. In some circumstances, however, the suspension system may allow the beam 201 to move towards the substrate 202 or cap 210 and become stuck. Such an extreme and undesirable displacement of the beam may be known as “jump shift.” For example, the bottom surface 201B of the beam 201 may become stuck to the opposing surface 206 of the substrate 202. Alternately, the top surface 201A of the beam 201 may become stuck to the opposing surface 210A of cap 210, for example when the accelerometer 100 is subject to an acceleration with a large acceleration vector normal to the plane of the top surface 206 of the substrate (i.e., in the Z direction), or during the packaging of the accelerometer, or when accelerometer is installed on a circuit board. In addition, contaminants between the beam 101 and substrate 102, such as moisture on one or both of the facing surfaces 105 and 106 of the beam 101 and substrate 102, may cause stiction or otherwise degrade performance of the accelerometer.

To reduce the risk of stiction, packing for MEMS devices typically leaves a generous gap between the movable component and the surface of a cap or other packaging, and between the beam and a substrate. In contrast to the embodiment in FIGS. 1A and 1B, for example, the gap 250 between the upper surface 201A of beam 201 and the inner surface 210A of the cap 210 of prior art accelerometer 200 in FIG. 2 may be at least 20 micrometers, and may be as large as 70 micrometers or more, for example. Similarly, the gap 251 between the bottom surface 202B of beam 201 and the top surface 206 of the substrate 202 is greater than 20 micrometers, and may be as large as 70 micrometers or more, for example.

Another concern arises in considering how to dampen the response of accelerometer 200. One way to moderate the response of an accelerometer is to encapsulate the accelerometer's beam in a cavity filled with high-viscosity gas, such as neon for example. The high-viscosity gas dampens the motion of the beam because it presents a resistance to beam motion. In practical terms, the high-viscosity gas presents a thick atmosphere through which the beam must move, and the very thickness of that atmosphere tends to resist the motion of the beam. However, the use of high-viscosity gasses is undesirable, in part because such gasses are not commonly used in semiconductor fabrication facilities. Providing such gasses therefore requires costs and efforts that make the fabrication facilities and processes more complicated and expensive. For example, to dampen the response of accelerometer 200, the volume 260 may be filled with such gases as air (having a viscosity of approximately 18) or argon (having a viscosity of approximately 22), to name but a few.

The accelerometers 100 and 200 may be compared and contrasted by considering their respective Q-factors (or “Q”). A system's Q-factor is a measure of its resonance characteristics. In other words, an accelerometer's suspended beam (e.g., 101, 201) may be forced to resonate by, for example, subjecting the accelerometer to a periodic acceleration. Although a beam does not resonate when detecting a linear acceleration, the compliance of the suspension system, and therefore the tendency of the beam to be displaced when subjected to acceleration, is correlated to the Q of the beam.

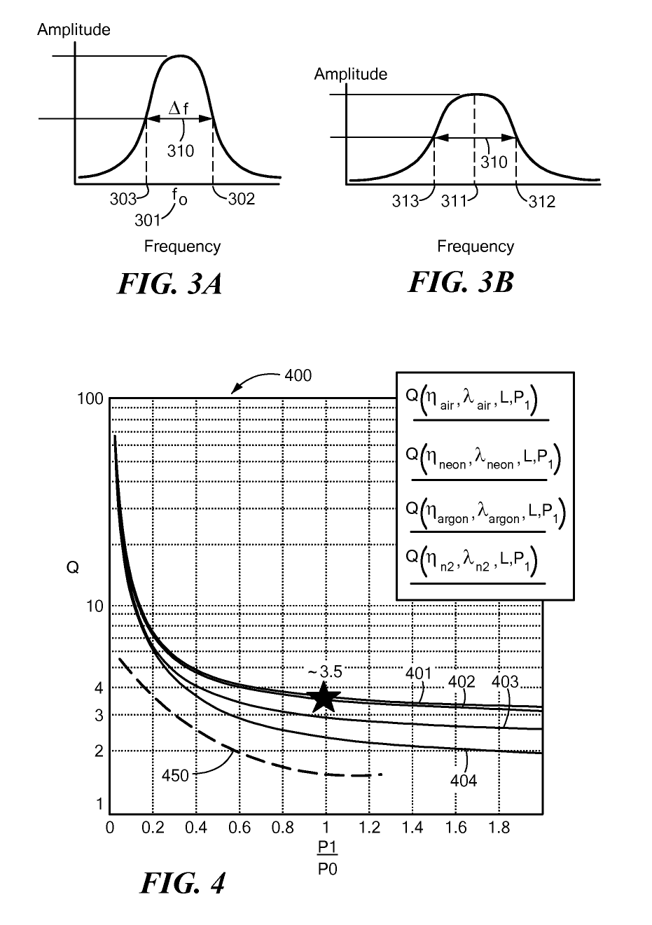

For a given accelerometer, the displacement of the beam (or alternately, the amplitude of the beam's cyclical displacement) will reach a maximum at a given frequency 301, which may be known as the “resonant” frequency (which may be designated as “fo”). For example, for an undamped accelerometer 200, the maximum displacement of the beam will occur at frequency fo, as schematically illustrated in FIG. 3A. At other frequencies, the displacement of the beam will be less than at the resonant frequency, as also schematically illustrated in FIG. 3A. At some frequency 302 above the resonant frequency (which may be known as the upper 3 dB frequency), and at another frequency 303 below the resonant frequency (which may be known as the lower 3 dB frequency), the displacement (or amplitude of the displacement) of the beam will be half of the displacement (or amplitude) at the resonant frequency.

The Q of an accelerometer is then determined as the ratio of the resonant frequency (fo) divided by difference (Δf or delta-f) 310 between the upper 3 dB frequency and the lower 3 dB frequency. The graph of an accelerometer's frequency response for a one accelerometer is schematically illustrated in FIG. 3A, while the frequency response for a dampened accelerometer is schematically illustrated in FIG. 3B. In FIG. 3A, the Q is the peak or resonant frequency (i.e., fo 301) divided by the frequency difference 310 between upper 3 dB frequency 302 and lower 3 dB frequency 303. In FIG. 3B, the Q is the peak or resonant frequency (i.e., fo 311) divided by the frequency difference 310 between upper 3 dB frequency 312 and lower 3 dB frequency 313. As such, Q is a dimensionless parameter.

A graph 400 comparing the Q of various damped accelerometers is presented in FIG. 4. Specifically, the graph 400 compares the Q of a prior art accelerometer, such as accelerometer 200, for example, filled with various dampening gasses at a variety of pressures, to an embodiment of an accelerometer with small gaps, such as accelerometer 100 for example, encapsulated with a low-viscosity gas. In each case, each such the gas may be known as a “fill gas”). In graph 400, gas pressure is represented as a ratio of the pressure (P1) of the fill gas to atmospheric pressure (P0), and the Q axis is logarithmic. As illustrated, the pressure of the gas may range from below 0.1 atmospheres to 1.2 atmospheres or more, and in some embodiments may be 0.2 atmospheres, 0.25 atmospheres, 0.3 atmospheres, 0.4 atmospheres, 0.5 atmospheres, 0.6 atmospheres, 0.7 atmospheres, 0.8 atmospheres, 0.9 atmospheres, or 1 atmosphere, or any pressure within the range.

As shown, the Q of the accelerometers tends to decrease with increasing pressure of the fill gas. Conversely, at low pressures, an accelerometer's Q tends to increase.

For example, for a prior art accelerometer may have a gap of 20 um between the inner surface of its cap and the facing surface of its beam (e.g., gap 250 in FIG. 2) with a fill gas at 1 atmosphere, nitrogen 401 and air 402 both yield a Q of about 3.5, while argon 403 yields a lower Q, and neon 404 yields an even lower Q. Generally, to dampen an accelerometer's response, a Q of less than 3.5 may be desirable, and indeed, some embodiments have a lower Q, such as 2.0 for example, or even lower.

In contrast, the Q of an exemplary embodiment of an accelerometer, e.g., accelerometer 100, may be held below 3.5 using even low-viscosity gas, and even at pressures as low as 0.2 atmospheres, as illustrated by curve 450 in graph 400 for example. By way of example, the gas in accelerometer 100, which yields the Q curve 450, may be nitrogen. The dampening provided by the small gap or gaps of accelerometer 100, as described above, is distinct from prior art accelerometers, even when the same gas (e.g., nitrogen) is used.

The relationship of Q to pressure of curve 450 in FIG. 4 is merely one example. Other accelerometers having different gap dimensions may have similar or different Q to pressure relationships, because, as the inventors have discovered, at these small scales (e.g., gaps less than 10 um), the Q is a function to both gap and pressure. This relationship does not hold for gap dimensions in prior art accelerometers, for example in which at least one of the gap dimensions is larger than 10 um.

Generally, for accelerometers with gap dimensions of less than 10 um, a smaller gap or gaps will yield lower Q at a given pressure. As such, for an accelerometer with given gap dimensions, the selection of the pressure of the fill gas can be reduced to raise the Q or increased to lower the Q. Similarly, for an accelerometer with a given gas pressure, gap dimensions may be selected within a range of up to 10 um to increase or lower the Q. In short, to produce a desired Q, a desired gap or gaps of less than 10 um may be specified, and the pressure will then be determined by the Q and the gap, or a desired pressure may be specified, and the gap dimensions will be determined by the Q and the pressure.

An additional advantage of the accelerometer 100 is that the pressure of the fill gas can be set and maintained at a low level (e.g., as low as 0.2 atmospheres in the example of curve 450 in FIG. 4). If the hermetic seal between the substrate 102 and cap 110 leaks, the pressure within the volume 160 will increase, and, as shown by curve 450 in FIG. 4, the Q of the accelerometer will decrease accordingly. As such, the integrity of the hermetic seal of an accelerometer may be tested by assessing the Q of the accelerometer. For example, if an accelerometer 100 is designed and fabricated to have a Q of approximately 2.0 with a fill gas pressure of 0.2 atmospheres, then a Q of less than 2.0 would indicate that the pressure within volume 160 has increased (e.g., to approximately one atmosphere), meaning that the hermetic seal has failed.

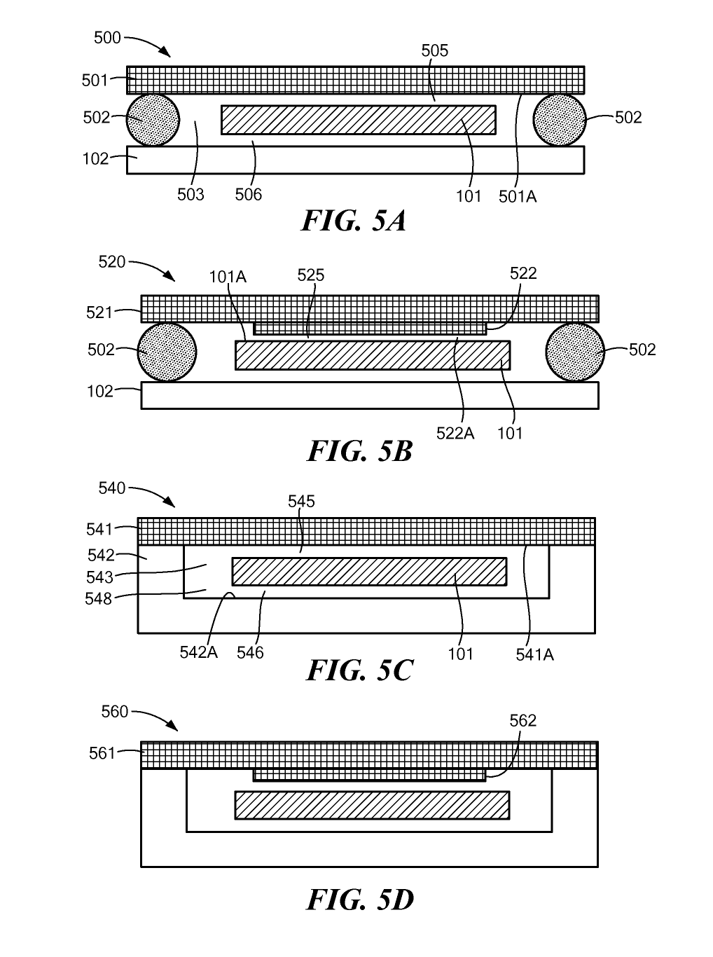

A number of alternate embodiments are schematically illustrated in FIGS. 5A-5D. An accelerometer 500 is schematically illustrated in FIG. 5A, and includes a beam 101 suspended above a substrate 102. A cap 501 is mounted to the substrate 102 by intermediate layer 502, and together, the substrate 102, cap 501 and intermediate layer 502 form a hermetic cavity 503 surrounding the beam 101. Similar to the gaps 150 and 151 in accelerometer 100 in FIGS. 1A and 1B, the gap 506 between the beam 101 and substrate 102, and the gap 501 between the beam 101 and the inner surface 501A of the cap 501 are preferably not greater than 10 um, and in some embodiments may be as small as 5 um or less. Various embodiments may gaps of 2 um, 3 um or 4 um. Further, the gaps between a beam and cap need not be the same as the gap between the beam and substrate.

In various embodiments, the intermediate layer 502 may be solder, or a frit such as a glass frit, or other medium capable of hermetically securing the cap 501 to the substrate 102.

Although accelerometers 100 and 500 have caps with planar inner surfaces 110A and 501A, that is not a limitation of all embodiments. In some embodiments, the narrow gap may be created by a portion that protrudes from a surface facing the beam. For example, FIG. 5B schematically illustrates an embodiment of an accelerometer 520, which has many of the same elements as accelerometer 500. However, accelerometer 520 includes a cap 521 that has a portion 522 that protrudes from the cap 521 in the direction of the beam 101. The protruding portion 522 may be known as a “mesa” or “table.”

The mesa 522 presents a surface of the cap 521 opposite the surface 101A of beam 101, and defines the gap 525 between the beam 101 and cap 521. In some embodiments, the surface 522A presented by mesa 522 to the beam surface 101A may be same size and shape as the beam surface 101A. In other embodiments, the surface 522A presented by mesa 522 to the beam surface 101A may be larger than, or smaller than, the beam surface 101A. However, if the surface area of surface 522A is made too small, then the damping effects of the gap 525 may be lost. The appropriate surface area of surface 522A may be determined based on the amount of desired damping.

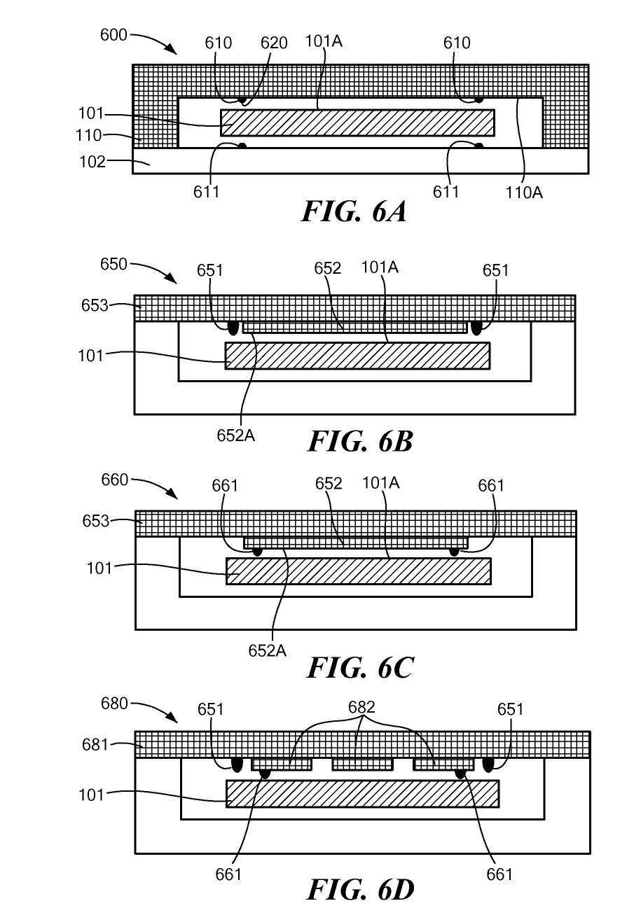

In some embodiments, a mesa (e.g., 681) may include several mesa portions 682 which together act as a single mesa to define the surface area, and gap between mesa and beam (101). Two examples are illustrated in FIG. 6D, although any mesa (with or without accompanying standoffs 651 or 661; as standoff may also be known as a “bump”) could have component portions as illustrated.

Another embodiment of an accelerometer 540 is schematically illustrated in FIG. 5C. In this embodiment, the substrate 542 includes a cavity 548, and the beam 101 resides within the cavity 548, such that the gap 546 between the beam 101 and bottom surface 542A of the cavity 542 is preferably not greater than 10um, and in some embodiments may be as small at 5 um or less. A cap 541 is hermetically secured to the substrate 542 so as to form a hermetically sealed volume 543 with the cavity 548, and the gap 545 between the beam 101 and inner surface 541A of the cap 541 is preferably not greater than 10 um, and in some embodiments may be as small at 5 um or less.

Yet another embodiment if an accelerometer 560 is schematically illustrated in FIG. 5D. Accelerometer 560 is similar to accelerometer 540, except that the cap 561 of accelerometer 560 includes a mesa 562. Mesa 562 is similar to mesa 522 in accelerometer 520.

Although accelerometers 520 and 560 each schematically illustrate a mesa on their respective caps, other embodiments may include a mesa on a substrate, and some embodiments includes a mesa on both the cap and substrate.

To address the risk of stiction, some embodiments may optionally include an anti-stiction coating, or one or more standoffs, such as standoff 610, as schematically illustrated in FIG. 6A. The standoff 610 protrudes from the inner surface 110A of cover 100. The standoff 610 prevents the beam 101 from contacting the inner surface 111 of cover 110. A standoff 130 has a small surface area at its tip 130A, so that if the beam 101 comes into contact with the standoff 130, there is little surface area by which stiction may occur. For example, the surface area of the tip 620 of a standoff 610 is several orders of magnitude smaller than the area of be surface 101A of the beam 101. In contrast, the surface area of a mesa opposite a surface of a beam is a substantial portion of that beam surface. For example, while the tip of a standoff (651, 652) that contacts the beam has a very small surface area, and is several orders of magnitude smaller that the surface of the mesa (652A). In some embodiments, the surface of a mesa (652A) may be at least 10 percent, 20 percent, 30 percent, 40 percent, or half or more of the area of the opposing surface 101A of a beam 101. In some embodiments, surface of a mesa (652A) may be ninety percent of that surface area, or even larger than that surface area.

Although standoff 130 is shown as extending from the inner surface 111 of cover 110, a standoff could be included on any surface that presents a risk of stiction, as schematically illustrated by standoffs 611 on substrate 102, for example. Some embodiments, such as accelerometer 650 schematically illustrated in FIG. 6B for example, standoffs 651 may be disposed around a mesa 652. The dimensions of the standoffs are such that the beam 101 will contact the standoffs 651 before reaching the mesa 652 of cap 653, in the event that the beam 101 is displaced in the direction of the mesa 652. In an alternate embodiment 660, one or more standoffs 661 may be on the mesa 652 itself, as schematically illustrated in FIG. 6C.

Although illustrated as individual caps in the embodiments above, in some embodiments, the accelerometer may be a portion of a device wafer, and the cap (e.g., caps or covers 521, 541, 561, 110, 653, for example) may be a portion of a cap wafer. Indeed, in some embodiments, the cap wafer may be an ASIC or other integrated circuit wafer, such that each cap portion of the cap wafer may be a “smart cap,” which includes at least one of integrated circuitry (e.g., active devices such as transistors), electrical conduits, or terminals, etc. In various embodiments, the cap wafer may optionally include mesa portions, standoffs, or both.

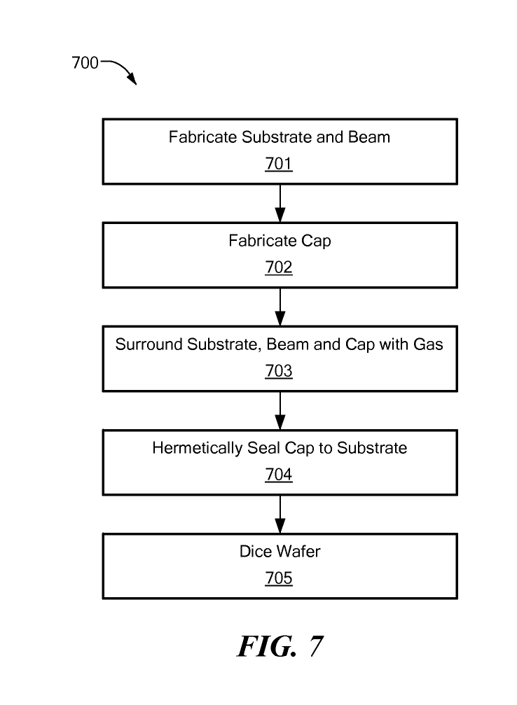

An embodiment of a method 700 of fabricating an accelerometer is presented in FIG. 7, and begins with the step of fabricating the substrate, and beam suspended from the substrate (step 701). In some embodiments, a substrate wafer is fabricated, and includes a number of substrates with a corresponding number of suspended beams.

The cap is fabricated in n step 702. One advantage of various embodiment is that some caps, such as cap 110 for example, may be fabricated without the need for deep silicon etching, and therefore may avoid the need to employ an expensive silicon deep etch tool. In other words, using cap 110 as an example, because the inner surface 110A of cap 110 does not need to be as far from the beam as in prior art accelerometers (such as accelerometer 200 for example), the cap does not need to be as deeply etched. Rather, the shallow cavity 110B in cap 110 can be formed by controlled shallow silicon etch, for example on a cap wafer. Alternately, in some embodiments, such as accelerometer 500 for example, etching a cavity in the cap or cap wafer can be avoided entirely, and the gap 505 can be controlled by controlling the thickness of the intermediate layer 502.

In addition, these techniques provide a thinner accelerometer and reduce the die package vertical profile, as compared to prior art accelerometers, such as accelerometer 200 for example.

At step 703, the substrate, beam and cap or cap wafer are surrounded by a gas, such as a low viscosity gas. However, in some embodiments, even high viscosity gasses may be used, for example if very high damping is desired.

Then, at step 704, the cap, or cap wafer, is hermetically sealed to the substrate, or substrate wafer.

Optionally, if the substrate is a substrate wafer and the cap is a cap wafer, the bonded wafers may be diced (705) to yield a number of individual capped, damped accelerometers.

Although the accelerometer schematically illustrated and discussed above are capacitance-type accelerometers, other accelerometers measure the displacement of the beam in other ways. For example, some accelerometers measure the displacement of a beam by use of piezo elements in the suspension system. However, for ease of illustration, examples of capacitive MEMS accelerometers are discussed herein, with the understanding that the principles disclosed are not limited to capacitance-based accelerometers, and could be applied to other accelerometer, including piezo-based accelerometers for example.

The embodiments of the invention described above are intended to be merely exemplary; numerous variations and modifications will be apparent to those skilled in the art. All such variations and modifications are intended to be within the scope of the present invention as defined in any appended claims.

1. An accelerometer having a Q-factor of less than 2.0, the accelerometer comprising:
a substrate having a substrate surface;
a movable mass suspended from the substrate and configured to sense acceleration by moving parallel to the substrate, the movable mass having a first surface and a second surface opposite the first surface, the first surface facing the substrate surface and separated from the substrate surface by a first gap;
a cap having a cap surface, the cap coupled to the substrate and forming a hermetically sealed volume with the substrate and enclosing the movable mass, wherein the second surface is opposite the cap surface and is separated from the cap surface by a second gap;
a gas filling the volume at a pressure of less than 1 atmosphere, the gas having a viscosity of less than 25.0 μPa·s,
each of the first gap and the second gap being less than 10 um, such that the accelerometer has a Q-factor of less than 2.0 for motion of the movable mass parallel to the substrate.

2. The accelerometer of claim 1, wherein the gas is at a pressure below 0.5 atmospheres.

3. The accelerometer of claim 1, further comprising at least one standoff on the cap surface.

4. The accelerometer of claim 3, wherein the standoff is opposite the second surface when the movable mass is in a rest position.

5. The accelerometer of claim 1, further comprising a frit between the substrate and the cap, the frit securing the substrate to the cap and forming a hermetic seal between the substrate and the cap.

6. The accelerometer of claim 1, the cap further comprising a mesa, and a surface of the mesa comprising the cap surface.

7. The accelerometer of claim 6, the mesa further comprising a plurality of mesa portions.

8. The accelerometer of claim 6, the cap further comprising a plurality of standoffs around the mesa.

9. The accelerometer of claim 1, the substrate further comprising a mesa, and a surface of the mesa comprising the substrate surface.

10. The accelerometer of claim 9, the substrate further comprising a plurality of standoffs around the mesa.

11. A method of fabricating an accelerometer having a Q-factor of less than 2.0, the method comprising:
providing a substrate having a substrate surface;
suspending a movable mass from the substrate and configured to sense acceleration by moving parallel to the substrate, the movable mass having a first surface and a second surface opposite the first surface, the first surface facing the substrate surface and separated from the substrate surface by a first gap;
providing a gas around the substrate at a pressure of less than 1 atmosphere, the gas having a viscosity of less than 25.0 μPa·s;
providing a cap, the cap having a cap surface;
mounting the cap to the substrate such that the second surface is opposite the cap surface and is separated from the cap surface by a second gap, and such that the substrate and cap form a hermetically sealed volume and enclose the movable mass and trap some of the gas within the volume;
each of the first gap and the second gap being less than 10 um, such that the accelerometer has a Q-factor of less than 2.0 for motion of the movable mass parallel to the substrate.

12. The method according to claim 11, wherein providing a gas around the substrate comprises providing a gas around the substrate at a pressure of less than 0.5 atmospheres, the gas having a viscosity of less than 25.0 μPa·s.

13. The method according to claim 11, wherein the cap includes at least one standoff on the cap surface.

14. The method according to claim 13, wherein the standoff is opposite the second surface when the movable mass is in a rest position.

15. The method according to claim 11, further comprising providing a frit between the substrate and the cap, the frit securing the substrate to the cap and forming a hermetic seal between the substrate and the cap.

16. The method according to claim 11, wherein providing a cap further comprises providing a cap having a mesa, and a surface of the mesa comprising the cap surface.

17. The method according to claim 16, the mesa further comprising a plurality of mesa portions.

18. The method according to claim 16, the cap further comprising a plurality of standoffs around the mesa.

19. The method according to claim 11, wherein providing a substrate comprises providing a substrate having a mesa, and a surface of the mesa comprising the substrate surface.

20. The method according to claim 19, wherein providing a substrate having a mesa further comprises providing a substrate having a plurality of standoffs around the mesa.
